(19) United States
(12) Patent Application Publication
(10) Pub. No.: US 2026/0223539 A1
(43) Pub. Date: Jul. 30, 2026

(54) DISPLAY DEVICE, METHOD OF MANUFACTURING DISPLAY DEVICE AND ELECTRONIC DEVICE INCLUDING THE SAME

(71) Applicant: Samsung Display Co., Ltd., Yongin-Si (KR)

(72) Inventors: HANBIT KIM, Yongin-si (KR); HYENA KWAK, Yongin-si (KR); CHANYEOB SEOL, Yongin-si (KR); MYOUNGGEUN CHA, Yongin-si (KR); SANGGUN CHOI, Yongin-si (KR); Taehyun Hong, Yongin-si (KR)

(21) Appl. No.: 19/313,906

(22) Filed: Aug. 29, 2025

(30) Foreign Application Priority Data
Jan. 24, 2025 (KR) 10-2025-0011485

(51) Int. Cl. H10K 59/121; H10K 59/12; H10K 59/124

(52) U.S. Cl. CPC H10K 59/1213; H10K 59/1201; H10K 59/1216; H10K 59/124

(57) ABSTRACT

A display device includes a substrate, a first transistor on the substrate, a capacitor on the first transistor connected to a gate electrode of the first transistor, and a light-emitting device electrically connected to the first transistor, wherein the first transistor includes a semiconductor layer and a gate electrode with a first insulating layer therebetween, the capacitor includes a lower electrode including the gate electrode and an upper electrode with a second insulating layer therebetween, and the second insulating layer and the gate electrode have a same width.

### CROSS-REFERENCE TO RELATED APPLICATION

This application is based on and claims priority, under 35 USC §119, to Korean Patent Application No. 10-2025-0011485 filed on January 24, 2025 in the Korean Intellectual Property Office, the disclosure of which is incorporated by reference herein in its entirety.

### BACKGROUND

### Field

The present disclosure relates to a display device, a method of manufacturing the display device, and an electronic device including the same.

### Description of the Related Art

Recently, various types of lightweight and compact flat panel display devices have been developed. Flat panel display devices include liquid crystal displays (LCDs), field emission displays (FEDs), plasma display panels (PDPs), and organic light-emitting displays.

Among flat panel displays, organic light-emitting displays display images using organic light-emitting diodes (OLEDs), which emit light through the recombination of electrons and holes. These organic light-emitting diode displays have come to prominence as next-generation displays because they have fast response speeds and operate with low power consumption.

The background art described above is technical information that the inventor possessed for deriving the present disclosure or acquired in the process of deriving the present disclosure.

### SUMMARY

The present disclosure provides a display device having improved electrical characteristics and improved manufacturing process efficiency of the display device, a method of manufacturing the display device, and an electronic device including the same.

The problems to be solved by the present disclosure are not limited to the problems mentioned above, and other problems and advantages of the present disclosure that are not mentioned may be understood by the following description and will be more clearly understood by the embodiments of the present disclosure. In some embodiments, it will be appreciated that the problems to be solved by and advantages of the present disclosure may be realized by the means and combinations thereof recited in the patent claims.

According to an aspect of the disclosure, there is provided a display device including a substrate, a first transistor on the substrate, a capacitor on the first transistor connected to a gate electrode of the first transistor, and a light-emitting device electrically connected to the first transistor, wherein the first transistor includes a semiconductor layer and the gate electrode with a first insulating layer therebetween, the capacitor includes a lower electrode including the gate electrode and an upper electrode with a second insulating layer therebetween, and the second insulating layer and the gate electrode have a same width.

In some embodiments, a thickness of the gate electrode may be about 30 nm to about 250 nm.

In some embodiments, a thickness of the second insulating layer may be about 10 nm to about 150 nm.

In some embodiments, a ratio of a thickness of the gate electrode to a thickness of the second insulating layer may be about 1.5 to about 5.

In some embodiments, a width of the gate electrode may be greater than a width of the upper electrode.

In some embodiments, the display device may further include a third insulating layer on the first insulating layer to cover the capacitor.

In some embodiments, the display device may further include a second transistor and a third transistor on the capacitor, wherein the second transistor and the third transistor are in a same layer.

In some embodiments, the first transistor may include a driving transistor, and the second transistor and the third transistor may include switching transistors.

In some embodiments, the capacitor may include a storage capacitor.

In some embodiments, the gate electrode may include amorphous silicon.

According to another aspect of the disclosure, there is provided a method of manufacturing a display device including disposing a semiconductor layer on a substrate, sequentially and continuously forming a first insulating layer, a first conductive layer, and a second insulating layer on the semiconductor layer, and simultaneously patterning the first conductive layer and the second insulating layer, wherein the first conductive layer is patterned to form a gate electrode, and the gate electrode and the patterned second insulating layer on the gate electrode have a same width.

In some embodiments, the method may further include stacking an upper electrode on the second insulating layer.

In some embodiments, the upper electrode may be stacked using chemical vapor deposition (CVD) or sputtering.

In some embodiments, the semiconductor layer, the first insulating layer, and the gate electrode may form a first transistor, and the gate electrode, the second insulating layer, and the upper electrode form a capacitor.

In some embodiments, in the continuously forming, a second conductive layer may be further formed on the second insulating layer, and the second conductive layer may be sequentially and continuously formed together with the first insulating layer, the first conductive layer, and the second insulating layer.

In some embodiments, the method may further include patterning the second conductive layer to form an upper electrode after the continuous forming of the first insulating layer, the first conductive layer, and the second insulating layer and before the patterning of the first conductive layer and the second insulating layer.

In some embodiments, a width of the gate electrode may be greater than a width of the upper electrode.

In some embodiments, the first insulating layer, the first conductive layer, the second insulating layer, and the second conductive layer may be continuously formed using a CVD method.

In some embodiments, the first conductive layer and the second conductive layer may include amorphous silicon.

In some embodiments, a thickness of the second insulating layer may be about 10 nm to about 150 nm.

According to another aspect of the disclosure, there is provided an electronic device including a memory storing at least one program, a processor configured to operate by executing the at least one program, a display device configured to receive data from the processor and to provide visual information, and a power module configured to supply power to the display device, wherein the display device includes a substrate, a first transistor on the substrate, a capacitor on the first transistor connected to adjust a gate electrode of the first transistor, and a light-emitting device electrically connected to the first transistor, wherein the first transistor includes a semiconductor layer and the gate electrode with a first insulating layer therebetween, the capacitor includes a lower electrode and an upper electrode formed by the gate electrode with a second insulating layer therebetween, and the second insulating layer and the gate electrode have the same width.

In some embodiments, a thickness of the second insulating layer may be 10 nm to 150 nm.

In some embodiments, a ratio of the thickness of the gate electrode to the thickness of the second insulating layer may be 1.5 to 5.

### BRIEF DESCRIPTION OF THE DRAWINGS

The following drawings attached to this specification illustrate embodiments of the present disclosure and, together with the detailed description of the invention described below, serve to further understand the technical idea of the present disclosure; therefore, the present disclosure should not be interpreted as being limited to matters described in such drawings:

FIG. 1 is a plan view schematically illustrating an example of a display device according to an embodiment of the present disclosure;

FIG. 2 is a perspective view schematically illustrating the display device of FIG. 1 in a bent state;

FIG. 3 is a schematic diagram illustrating a structure of the display device of FIG. 1;

FIG. 4 is a circuit diagram illustrating an example of an equivalent circuit of a sub-pixel of the display device of FIG. 1;

FIG. 5 is a cross-sectional view schematically illustrating an example taken along line A-A' of FIG. 1;

FIG. 6 is a cross-sectional view schematically illustrating an example of a first transistor and a first capacitor of FIG. 5;

FIGS. 7 to 9 are cross-sectional views schematically illustrating an example of a method of manufacturing the first transistor and the first capacitor of FIG. 6;

FIGS. 10 and 11 are cross-sectional views schematically illustrating another example of a method of manufacturing the first transistor and the first capacitor of FIG. 6;

FIG. 12 is a block diagram of an electronic device according to an embodiment; and

FIG. 13 is a schematic diagram of electronic devices according to various embodiments.

### DETAILED DESCRIPTION

The present disclosure may apply various transformations and have various embodiments, specific embodiments are illustrated in the drawings and described in detail in the detailed description. Effects and features of the present disclosure, and methods for achieving them will become clear with reference to the embodiments described below in detail together with the drawings. However, the present disclosure is not limited to the embodiments disclosed below and may be implemented in various forms.

In the following embodiments, the terms first, second, and the like do not have limited meaning but are used for the purpose of distinguishing one component from another component.

In the following embodiments, the expressions used in the singular such as “a,” “an,” and “the” are intended to include the plural forms as well, unless the context clearly indicates otherwise.

In the following embodiments, it will be understood that the terms such as “including,” “comprising,” and “having” specify the presence of stated features or components, but do not preclude the presence or addition of one or more other features or components.

In the following examples, when a part, such as a film, region, component, etc. is mentioned to be on or above another part, it includes not only a case in which the part is directly on top of the other part, but also a case in which another film, region, component, etc. is interposed in between.

In the drawings, components may be exaggerated or reduced in size for convenience of description. For example, the sizes and thicknesses of the respective components shown in the drawings are arbitrarily shown for convenience of description, and thus one or more embodiments are not necessarily limited thereto.

Hereinafter, embodiments of the present disclosure will be described in detail with reference to the accompanying drawings, and when described with reference to the drawings, the same or corresponding components are given the same reference numerals.

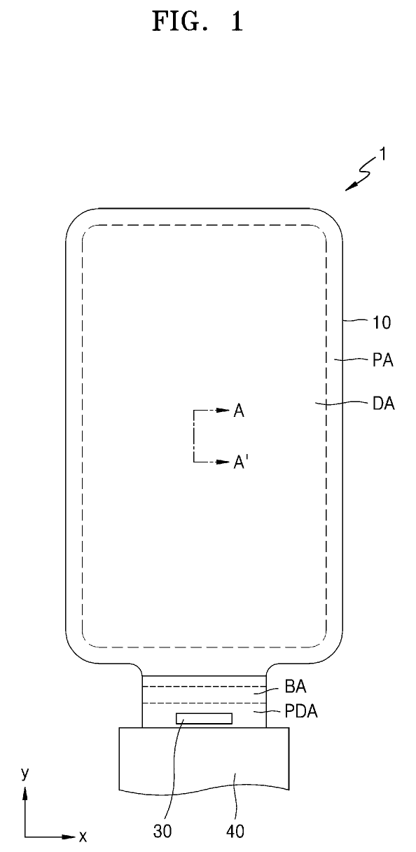

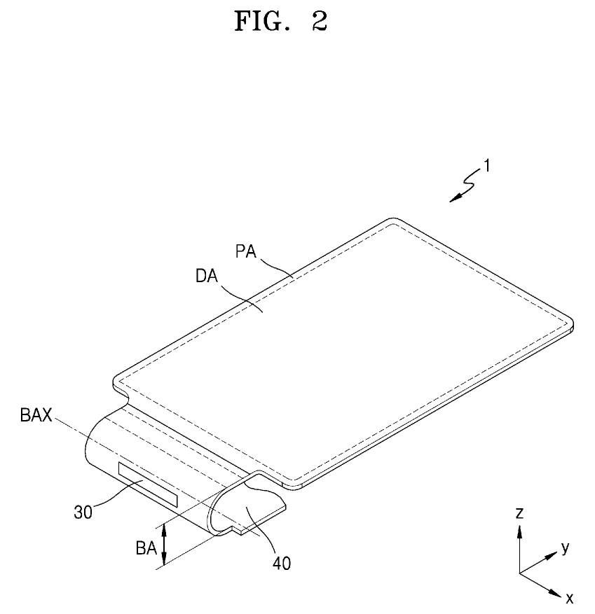

FIG. 1 is a plan view schematically illustrating an example of a display device 1 according to an embodiment of the present disclosure, and FIG. 2 is a perspective view schematically illustrating the display device 1 of FIG. 1 in a bent state.

Herein, a 'first direction x' may be a width direction of the display device 1 or a direction parallel to a bending axis BAX to be described below. A 'second direction y' may be a length direction of the display device 1, a 'third direction z' may be interpreted as a stacking direction of the components of the display device 1 to be described below or a direction perpendicular to both the first direction x and the second direction y, and the first direction x, the second direction y, and the third direction z may be perpendicular to each other.

Referring to FIGS. 1 and 2, the display device 1, which displays a moving image or still image, may display a screen on a display panel 10 or perform input and output of data. Such a display device 1 may be used as a display screen of various electronic devices, such as a television, a laptop, a monitor, a billboard, an Internet of Things (IOT) device, etc., as well as portable electronic devices, such as a mobile phone, a smartphone, a tablet personal computer (PC), a mobile communication terminal, an electronic notebook, an electronic book, a portable multimedia player (PMP), a navigation device, an ultra mobile PC (UMPC).

In some embodiments, the display device 1 according to an embodiment may be used in the electronic device 1000, such as a wearable device, e.g., a smart watch, a watch phone, a glasses-type display, and a head mounted display (HMD).

In some embodiments, the display device 1 according to an embodiment may be used as a display of various electronic devices, for example, a dashboard of an automobile, a center information display (CID) placed on an instrumental panel, a center fascia, and a dashboard of an automobile, a room mirror display replacing a side mirror of an automobile, and a display placed on the back of a front seat as entertainment for the rear seats of an automobile.

The display device 1 according to an embodiment of the present disclosure may include a display region DA in which a plurality of pixels are positioned and a peripheral region PA positioned outside the display region DA. The peripheral region PA may include a pad region PDA which is located on one side of the display region DA and which is a region in which various electronic components, such as an integrated circuit 30 or a flexible circuit board 40 is electrically attached, and a bent region BA between the display region DA and the pad region PDA. The display region DA, the peripheral region PA, the pad region PDA, and the bent region BA may be defined on a substrate.

Meanwhile, FIG. 1 is a plan view illustrating the shape of a substrate, etc. during a manufacturing process of the display device 1, and the substrate, etc. may have a bent region BA bent based on a bending axis BAX extending in the first direction x, as illustrated in FIG. 2. Here, a bending direction is set so that the pad region PDA is located behind the display region DA. Accordingly, the area of the peripheral region PA perceived by a user may be minimized.

A circuit cover may be attached to the integrated circuit 30 and the flexible circuit board 40 of the pad region PDA. The circuit cover may protect the integrated circuit 30 and the flexible circuit board 40 from mechanical shock and add waterproofing and insulation performance to the integrated circuit 30 and the flexible circuit board 40.

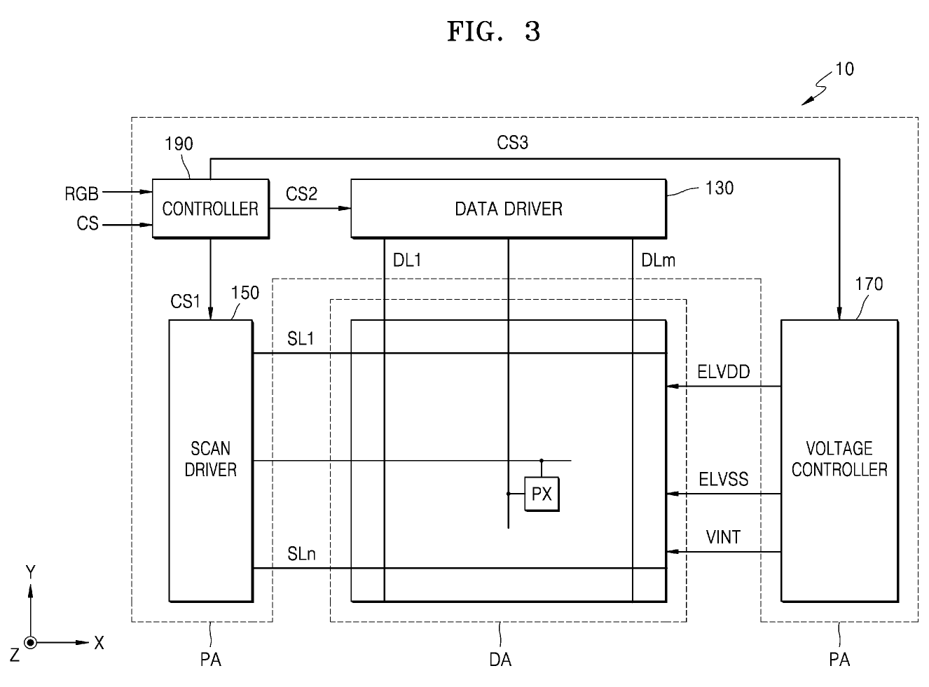

FIG. 3 is a block diagram schematically illustrating a structure of the display device 1 of FIG. 1.

Referring to FIG. 3, a plurality of scan lines SL1, ..., SLn extending in the first direction x, a plurality of data lines DL1, ..., DLm extending in the second direction y perpendicular to the first direction x, and a plurality of sub-pixels PX may be positioned in the display region DA. Here, m and n are each natural numbers.

Lines capable of applying electrical signals to a plurality of sub-pixels PX may include the plurality of scan lines SL1, ..., SLn, the plurality of data lines DL1, ..., DLm, etc. The plurality of scan lines SL1, ..., SLn may be arranged in a plurality of rows extending in the first direction X, for example, to transfer scan signals to the sub-pixels PX, the plurality of data lines DL1, ..., DLm may be arranged in a plurality of columns extending in the second direction Y, for example, to transfer data signals to the sub-pixels PX, and the plurality of sub-pixels PX may be positioned at intersections of the plurality of scan lines SL1, ..., SLn and the plurality of data lines DL1, ..., DLm.

Each sub-pixel PX may include a light-emitting device to emit red, green, blue, or white light. For example, each sub-pixel PX may include, but is not limited to, an organic light-emitting diode OLED as a light-emitting device.

In the peripheral region PA, a data driver 130 that provides data signals to the display region DA, a scan driver 150 that provides scan signals to the display region DA, a voltage controller 170 that controls voltages supplied to the display region DA, and a controller 190 that may control the data driver 130, scan driver 150, and voltage controller 170 may be arranged.

The voltage controller 170 may generate and control a first voltage ELVDD, a second voltage ELVSS, and an initialization voltage VINT provided to the display region DA.

The first voltage ELVDD, the second voltage ELVSS, and the initialization voltage VINT may be applied to the plurality of sub-pixels PX. For example, the first voltage ELVDD may be a positive voltage, and the second voltage ELVSS may be a negative voltage or ground voltage. That is, the second voltage ELVSS may have a lower level than that of the first voltage ELVDD.

The controller 190 may receive image signals RGB and a control signal CS from the outside (e.g., a system board). The controller 190 may convert a data format of the image signals RGB to match interface specifications of the data driver 130 and generate image data DATA. The controller 190 may provide the image data DATA, which has been generated by converting the data format of the image signals RGB, to the data driver 130.

The controller 190 may generate and output a first control signal CS1 and a second control signal CS2 in response to the control signal CS provided from the outside. The first control signal CS1 may be defined as a scan control signal, and the second control signal CS2 may be defined as a data control signal. The first control signal CS1 may be provided to the scan driver 150. The second control signal CS2 may be provided to the data driver 130.

The scan driver 150 may generate a plurality of scan signals in response to the first control signal CS1. The plurality of scan signals may be applied to the plurality of sub-pixels PX via the plurality of scan lines SL1, ..., SLn.

The data driver 130 may generate a plurality of data voltages corresponding to the image data DATA in response to the second control signal CS2. The plurality of data voltages may be applied to the plurality of sub-pixels PX via the data lines DL1, ..., DLm. The data driver 130 may simultaneously provide the data voltages generated in units of sub-pixel rows to the plurality of sub-pixels PX via the data lines DL1, ..., DLm.

The plurality of sub-pixels PX may receive the plurality of data voltages in response to the plurality of scan signals. The plurality of sub-pixels PX may display an image by emitting light with a brightness corresponding to the plurality of data voltages. The plurality of sub-pixels PX may display the image by emitting light sequentially or simultaneously.

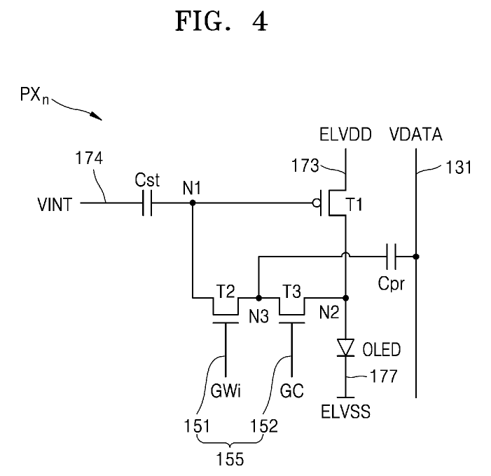

FIG. 4 is a circuit diagram illustrating an example of an equivalent circuit of a sub-pixel of the display device 1 of FIG. 1.

Referring to FIG. 4, each of the plurality of sub-pixels PX may include a first transistor T1, a second transistor T2, a third transistor T3, and an organic light-emitting diode (OLED) electrically connected to the first transistor T1.

Among the plurality of sub-pixels PX of FIG. 3, the sub-pixel PX connected to an i-th scan line 155 among the plurality of scan lines SL1, ..., SLn and a j-th data line 131 among the plurality of data lines DL1, ..., DLm may be defined as an n-th sub-pixel PXn. Here, each of i and j may be a natural number.

The i-th scan line may include a first scan line 151 and a second scan line 152. The first scan line 151 and the second scan line 152 may respectively transfer scan signals GWi and GC to the n-th sub-pixel PXn.

The data line 131 may transfer a data voltage VDATA to the n-th sub-pixel PXn. The data voltage VDATA may have a voltage level corresponding to the image signal RGB input to the display device (1 in FIG. 1).

The first voltage line 173 may transfer a first voltage ELVDD to the n-th sub-pixel PXn, a second voltage line 177 may transfer a second voltage ELVSS to the n-th sub-pixel PXn, and an initialization voltage line 174 may transfer an initialization voltage VINT to the n-th sub-pixel PXn.

A first transistor T1 may be a P-type transistor having a low-temperature polycrystalline silicon (LTPS) semiconductor layer or an oxide semiconductor layer. However, this is an example and the first transistor T1 may be an N-type transistor.

Second and third transistors T2 and T3 may be N-type transistors having an LTPS semiconductor layer or an oxide semiconductor layer. However, this is an example and the second and/or third transistors T2 and T3 may be P-type transistors.

The first transistor T1 may include a first gate electrode, a first driving electrode, and a second driving electrode. The first gate electrode of the first transistor T1 may be connected to a first node N1, the first driving electrode may be connected to the first voltage line 173, and the second driving electrode may be connected to a second node N2. The first transistor T1 may be referred to as a driving transistor.

The second transistor T2 may include a second gate electrode, a first switching electrode, and a second switching electrode. The second gate electrode of the second transistor T2 may be connected to the first scan line 151, the first switching electrode may be connected to the first node N1, and the second switching electrode may be connected to a third node N3. The second transistor T2 may be referred to as a switching transistor or a scan transistor.

The third transistor T3 may include a third gate electrode, a first initialization electrode, and a second initialization electrode. The third gate electrode of the third transistor T3 may be connected to the second scan line 152, the first initialization electrode may be connected to the third node N3, and the second initialization electrode may be connected to the second node N2. The third transistor T3 may be referred to as a switching transistor or an initialization transistor.

Meanwhile, each of the plurality of sub-pixels PX may further include a first capacitor Cst and a second capacitor Cpr.

A first lower electrode of the first capacitor Cst may be connected to the first node N1, and a first upper electrode may be connected to the initialization voltage line 174. The first capacitor Cst may be referred to as a storage capacitor.

The first capacitor Cst may store a voltage between the first node N1 and the initialization voltage line 174. Based on a voltage stored in the first capacitor Cst, the first capacitor Cst may control a gate voltage of the first transistor T1 to determine the amount of driving current flowing through the first transistor T1. The OLED may emit light based on the driving current.

The second lower electrode of the second capacitor Cpr may be connected to the third node N3, and the second upper electrode may be connected to the data line 131.

The second capacitor Cpr may store a voltage between the third node N3 and the data line 131. In some embodiments, the second capacitor Cpr may initialize the first voltage ELVDD through the second node N2 and the third transistor T3.

A first electrode of the OLED may be connected to the second node N2, and a second electrode of the OLED may be connected to the second voltage line 177. The first electrode of the OLED may be referred to as an anode electrode or a pixel electrode, and the second electrode of the OLED may be referred to as a cathode electrode or a common electrode.

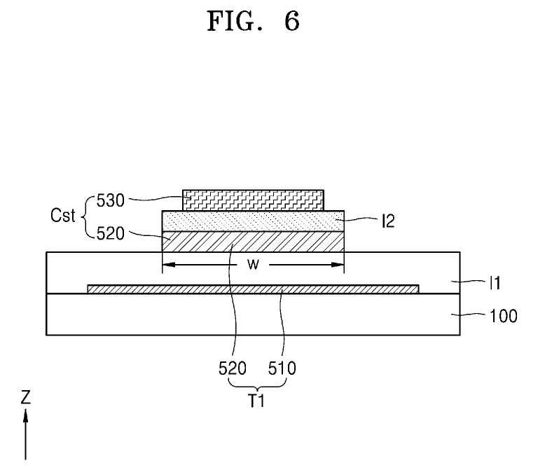

Although FIG. 4 illustrates the pixel circuit as including three thin film transistors and two capacitors, a pixel circuit including transistors and capacitors, which are described in detail with reference to FIG. 6 and the subsequent drawings, may include two, four, five, or more thin film transistors, and the pixel circuit may include one, three, or more capacitors.

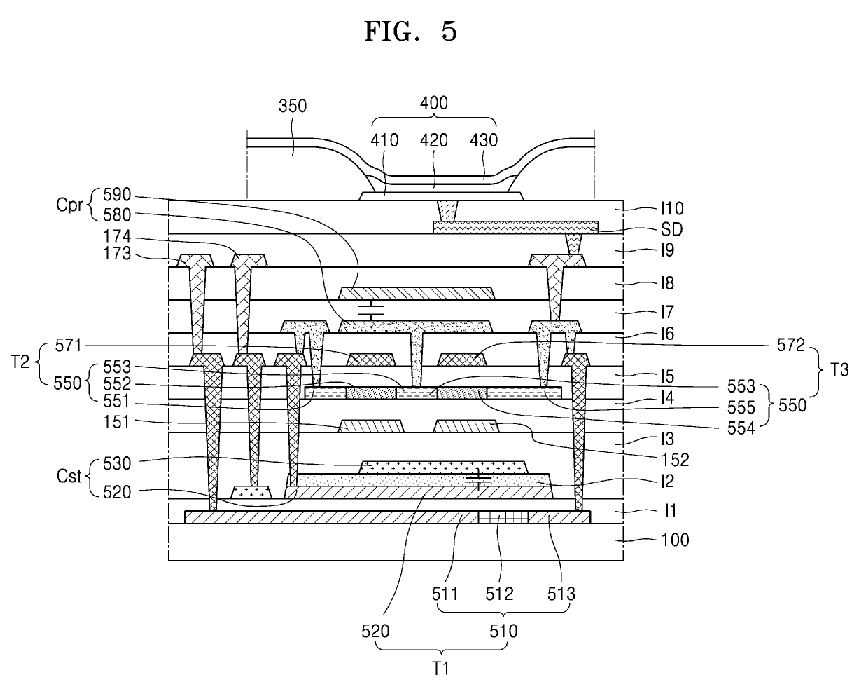

FIG. 5 is a cross-sectional view schematically illustrating an example taken along line A-A' of FIG. 1.

Referring to FIG. 5 together with FIG. 4, on a substrate 100 of a sub-pixel PX according to an embodiment of the present disclosure, a first transistor T1, a second transistor T2 and a third transistor T3 positioned on the first transistor T1, and a light-emitting device 400 positioned on the second transistor T2 and the third transistor T3 and electrically connected to the first transistor T1 may be arranged. Here, the second transistor T2 and the third transistor T3 may be located in a same layer. The light-emitting device 400 of FIG. 5 may refer to the same device as the OLED of FIG. 4.

In an embodiment, the substrate 100 may include a transparent glass material including SiO₂ as a main component. However, without being limited thereto, the substrate 100 may also include a transparent plastic material. Plastic materials may include polyethersulfone (PES), polyacrylate (PAR), polyetherimide (PEI), polyethylene naphthenate (PEN), polyethylene terephthalate (PET), polyphenylene sulfide (PPS), polyallylate, polyimide, polycarbonate (PC), cellulose triacetate (TAC), cellulose acetate propionate (CAP), etc.

A first semiconductor layer 510 may be formed on the substrate 100. The first semiconductor layer 510 may include a first source region 511, a first drain region 513, and a first channel region 512 located between the first source region 511 and the first drain region 513.

In an embodiment, the first semiconductor layer 510 may include a first source region 511 and a first drain region 513 formed by doping impurities on opposite sides of the first channel region 512. Here, the impurities may vary depending on the type of the first transistor T1 and may include an N-type impurity or a P-type impurity. That is, the first channel region 512, the first source region 511 located on one side of the first channel region 512 and the first drain region 513 located on the other side of the first channel region 512 may be referred to as the first semiconductor layer 510.

The first source region 511 or the first drain region 513 formed by doping may be interpreted as the source electrode (or the first driving electrode) or the drain electrode (or the second driving electrode) of the first transistor T1 in some cases. In some embodiments, the positions of the first source region 511 and the first drain region 513 may be interchanged depending on the impurities doped into the first semiconductor layer 510.

The first semiconductor layer 510 may include at least one of polycrystalline silicon or an oxide semiconductor. For example, the first semiconductor layer 510 may be a layer including LTPS, IGZO, IGO, etc.

As an optional embodiment, a buffer layer may be formed between the substrate 100 and the first semiconductor layer 510. The buffer layer may block impurities during a crystallization process to form polycrystalline silicon, thereby improving the characteristics of the polycrystalline silicon and providing a flat surface on the buffer layer.

A first insulating layer l1 may be formed on the first semiconductor layer 510 to cover the first semiconductor layer 510. A first conductive layer including a first gate electrode 520 may be formed on the first insulating layer l1. On a plane perpendicular to the stacking direction of the sub-pixels PX, the area of the first gate electrode 520 may be wider than the area of the first channel region 512 of the first transistor T1.

The first gate electrode 520 may form the first transistor T1 together with the first semiconductor layer 510. The first transistor T1 may receive a first voltage ELVDD from the first source region 511 and provide a driving current to the light-emitting device 400.

The sub-pixel PX according to an embodiment of the present disclosure may further include the first capacitor Cst and the second capacitor Cpr.

The first gate electrode 520 may function as the first lower electrode 520 of the first capacitor Cst. Accordingly, the integration density of the display device (1 in FIG. 1) may be increased, thereby increasing the area of the first capacitor Cst and the first transistor T1 and providing a high-quality image. However, the present disclosure is not limited thereto. As another embodiment, the first lower electrode 520 of the first capacitor Cst may be a separate and independent component from the first gate electrode 520 of the first transistor T1.

A second insulating layer l2 overlapping the first gate electrode 520 may be formed on the first gate electrode 520. The second insulating layer l2 may have the same width as that of the gate electrode 520. This will be described in detail below with reference to FIGS. 6 to 11.

A second conductive layer including a first upper electrode 530 of the first capacitor Cst may be formed on the second insulating layer l2. The first upper electrode 530 of the first capacitor Cst may form the first capacitor Cst together with the first lower electrode 520 of the first capacitor Cst. The first capacitor Cst may be referred to as a storage capacitor.

A third insulating layer l3 covering the first capacitor Cst may be formed on the first insulating layer l1. A third conductive layer including the first scan line 151 and the second scan line 152 that may receive the scan signals GWi and GC respectively may be formed on the third insulating layer l3.

A fourth insulating layer l4 may be formed on the third conductive layer to cover the third conductive layer. A second semiconductor layer 550 may be formed on the fourth insulating layer l4. The second semiconductor layer 550 may include a second source region 551, a second channel region 552, a second drain region 553, a third source region 553, a third channel region 554, and a third drain region 555.

The second channel region 552 may be located between the second source region 551 and the second drain region 553, and the third channel region 554 may be located between the third source region 553 and the third drain region 555. The second drain region 553 and the third source region 553 may refer to the same region.

Depending on the impurities doped into the second semiconductor layer 550, the positions of the second source region 551 and the second drain region 553 may be interchanged, and depending on the impurities doped into the second semiconductor layer 550, the positions of the third source region 553 and the third drain region 555 may be interchanged.

The second semiconductor layer 550 may be a layer including an oxide semiconductor, but is not limited thereto, and the second semiconductor layer 550 may also be a layer including polycrystalline silicon, for example, LTPS.

A fifth insulating layer l5 covering the second semiconductor layer 550 may be formed. A fourth conductive layer including a second gate electrode 571 and a third gate electrode 572 may be formed on the fifth insulating layer l5.

The second gate electrode 571 and the third gate electrode 572 may overlap the second channel region 552 and the third channel region 554, respectively. The second gate electrode 571 may form the second transistor T2 together with the second source region 551, the second channel region 552, and the second drain region 553. In some embodiments, the third gate electrode 572 may form the third transistor T3 together with the third source region 553, the third channel region 554, and the third drain region 555. Here, the second transistor T2 and the third transistor T3 may be located in a same layer.

The second transistor T2 may be referred to as a switching transistor or a scan transistor. In some embodiments, the third transistor T3 may be referred to as a switching transistor or an initialization transistor.

The first scan line 151 and the second scan line 152 located on the third insulating layer l3 and located in a same layer between the first transistor T1 and the second transistor T2 may be referred to as a second sub-gate electrode 151 and a third sub-gate electrode 152, respectively.

The second sub-gate electrode 151 and the third sub-gate electrode 152 may form a dual gate of the second transistor T2 and a dual gate of the third transistor T3 together with the second gate electrode 571 and the third gate electrode 572, respectively. As a result, the scan signals GWi and GC may be applied to the second transistor T2 and the third transistor T3, respectively.

The second sub-gate electrode 151 may overlap the second gate electrode 571, and the area of the second sub-gate electrode 151 in a plan view may be larger than the area of the second gate electrode 571. The third sub-gate electrode 152 may overlap the third gate electrode 572, and the area of the third sub-gate electrode 152 in a plan view may be larger than the area of the third gate electrode 572.

When the second transistor T2 and the third transistor T3 have dual gates, current flowing through the second transistor T2 and the third transistor T3 may be controlled more precisely, switching speeds of the second transistor T2 and the third transistor T3 may be improved by the interaction between the dual gates, and the second transistor T2 and the third transistor T3 may be driven at low power.

A sixth insulating layer l6 may be formed on the fourth conductive layer to cover the fourth conductive layer. A fifth conductive layer including a second lower electrode 580 of the second capacitor Cpr may be formed on the sixth insulating layer l6. The second lower electrode 580 of the second capacitor Cpr may be connected to the second transistor T2 and the third transistor T3 through a contact hole.

A seventh insulating layer l7 may be formed on the fifth conductive layer to cover the fifth conductive layer. A sixth conductive layer including a second upper electrode 590 of the second capacitor Cpr may be formed on the seventh insulating layer l7.

The second upper electrode 590 of the second capacitor Cpr may be located to overlap the second lower electrode 580 of the second capacitor Cpr. In some embodiments, the second upper electrode 590 of the second capacitor Cpr may form the second capacitor Cpr together with the second lower electrode 580 of the second capacitor Cpr. The second capacitor Cpr may be referred to as a program capacitor.

In some embodiments, the second upper electrode 590 of the second capacitor Cpr may include the data line 131 to which the data voltage VDATA is applied.

An eighth insulating layer l8 may be formed on the sixth conductive layer to cover the sixth conductive layer. A seventh conductive layer including the first voltage line 173 to which the first voltage ELVDD is applied and the initialization voltage line 174 to which the initialization voltage VINT is applied may be formed on the eighth insulating layer l8.

The first voltage line 173 may be connected to the first source region 511 of the first transistor T1 through a contact hole. Due to this, the first voltage ELVDD may be applied to the first source region 511 of the first transistor T1.

The initialization voltage line 174 may be connected to the first upper electrode 530 of the first capacitor Cst through a contact hole. Accordingly, the first capacitor Cst may store the initialization voltage VINT.

The first insulating layer l1, the second insulating layer l2, the third insulating layer l3, the fourth insulating layer l4, the fifth insulating layer l5, the sixth insulating layer l6, the seventh insulating layer l7, and the eighth insulating layer l8 may each include silicon nitride and/or silicon oxide.

A ninth insulating layer l9 may be formed on the seventh conductive layer to cover the seventh conductive layer. An eighth conductive layer SD that electrically connects the pixel electrode 410 of the light-emitting device 400 to the drain region 513 of the first transistor T1 may be formed on the ninth insulating layer l9. For example, the eighth conductive layer SD may be the second node N2 illustrated in FIG. 4.

A tenth insulating layer l10 may be formed on the eighth conductive layer SD to cover the eighth conductive layer SD. The light-emitting device 400 including the pixel electrode 410, and an intermediate layer 420 located between the pixel electrode 410 and the common electrode 430 and including a emission layer may be positioned on the tenth insulating layer l10. The light-emitting device 400 may be, for example, an organic OLED containing an organic material.

In an embodiment, the pixel electrode 410 may be an anode of the OLED, and the common electrode 430 may be a cathode of the OLED. However, the present disclosure is not limited thereto, and depending on a driving method of the display device, the pixel electrode 410 may be a cathode of the OLED and the common electrode 430 may be an anode of the OLED. When holes and electrons are injected into the intermediate layer 420 from each of the pixel electrode 410 and the common electrode 430 and excitons as combinations of the injected holes and electrons drop from an excited state to a ground state, light emission may occur.

The ninth insulating layer l9 and the tenth insulating layer l10 may each include organic substances, such as imide polymers, general-purpose polymers, such as polymethylmethacrylate (PMMA) or polystylene (PS), polymer derivatives having phenolic groups, acrylic polymers, aryl ether polymers, amide polymers, fluorinated polymers, p-xylene polymers, vinyl alcohol polymers, and blends thereof, or a stacked film of organic substances and inorganic substances.

The first to eighth conductive layers may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), amorphous silicon (a-Si), or copper (Cu).

The pixel electrode 410 may be a (semi)transparent electrode or a reflective electrode. When the pixel electrode 410 is a (semi)transparent electrode, the pixel electrode 410 may include, for example, ITO, IZO, ZnO, In₂O₃, IGO or AZO. When the pixel electrode 410 is a reflective electrode, the pixel electrode 410 may have a reflective film including Ag, Mg, Al, Pt, Pd, Au, Ni, Nd, Ir, Cr, and compounds thereof and a layer including ITO, IZO, ZnO, In2O3, IGO, or AZO. Of course, the present disclosure is not limited thereto, and the pixel electrode 410 may include various materials, and a structure of the pixel electrode 410 may also be modified in various manners, such as being single-layered or multi-layered.

A pixel definition film 350 covering the edge of the pixel electrode 410 may be placed on the tenth insulating layer l10. The pixel definition film 350 has an opening corresponding to each pixel, that is, an opening that exposes at least a portion of the light-emitting device 400, thereby defining the pixel. Here, the opening may be a light-emitting region. In some embodiments, the pixel definition film 350 may increase a distance between the edge of the pixel electrode 410 and the common electrode 430, thereby preventing arcs or the like from occurring between the edge of the pixel electrode 410 and the common electrode 430. The pixel definition film 350 may include an organic material, such as polyimide or hexamethyldisiloxane (HMDSO).

The intermediate layer 420 may be formed on the pixel electrode 410 exposed through the opening of the pixel definition film 350. The intermediate layer 420 may include a low molecular weight or high molecular weight material. When the intermediate layer 420 includes a low molecular weight material, the intermediate layer 420 may have a structure in which a hole injection layer (HIL), a hole transport layer (HTL), an emission layer (EML), an electron transport layer (ETL), and an electron injection layer (EIL) are stacked singly or complexly and may include various organic substances including copper phthalocyanine (CuPc), N,N'-di(naphthalene-1-yl)-N,N'-diphenyl-benzidine (NPB), tris-8-hydroxyquinoline aluminum (Alq3), etc. These layers may be formed by vacuum deposition.

When the intermediate layer 420 includes a polymer material, the intermediate layer 420 may usually have a structure including a HTL and an EML. Here, the HTL may include PEDOT, and the EML may include a polymer material, such as poly-phenylenevinylene (PPV) and polyfluorene. The structure of the intermediate layer 420 is not limited to that described above and may have various structures. For example, the intermediate layer 420 may include a single layer that spans a plurality of pixel electrodes 410 or may include a layer patterned to correspond to each of the plurality of pixel electrodes 410.

The second voltage ELVSS may be applied to the common electrode 430, and the common electrode 430 may be positioned to cover the display region (DA in FIG. 1). That is, the common electrode 430 may be formed integrally to cover a plurality of light-emitting devices 400. The common electrode 430 may be a (semi)transparent electrode or a reflective electrode. In case that the common electrode 430 is a (semi)transparent electrode, the common electrode 430 may have a layer including a metal having a small work function, i.e., Li, Ca, LiF/Ca, LiF/Al, Al, Ag, Mg, and compounds thereof, and a (semi)transparent conductive layer, such as ITO, IZO, ZnO, or In₂O₃. In case that the common electrode 430 is a reflective electrode, the common electrode 430 may have a layer including Li, Ca, LiF/Ca, LiF/Al, Al, Ag, Mg, and compounds thereof. Of course, the configuration and material of the common electrode 430 are not limited thereto and various modifications may be made.

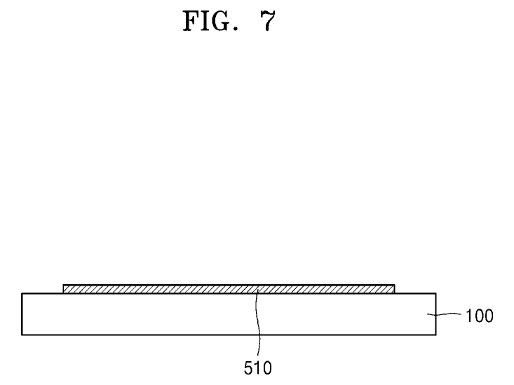

FIG. 6 is a cross-sectional view schematically illustrating an example of the first transistor T1 and the first capacitor Cst of FIG. 5, and FIGS. 7 to 9 are cross-sectional views schematically illustrating an example of a method of manufacturing the first transistor T1 and the first capacitor Cst of FIG. 6.

Referring to FIG. 6, as described above, the display device (1 of FIG. 1) according to an embodiment of the present disclosure may include a substrate 100, the first transistor T1 of the substrate 100, the first capacitor Cst positioned on the first transistor T1 and adjusting a gate voltage of the first transistor T1, and the light-emitting device (400 of FIG. 5) electrically connected to the first transistor T1.

The first transistor T1 may include the first semiconductor layer 510 and the first gate electrode 520 with the first insulating layer l1 therebetween, and the first capacitor Cst may include a first lower electrode 520 and a first upper electrode 530 including the first gate electrode 520 with the second insulating layer l2 therebetween. That is, the first gate electrode 520 of the first transistor T1 and the first lower electrode 520 of the first capacitor Cst may be terms referring to the same component.

Hereinafter, for convenience of description, the 'first semiconductor layer 510' is briefly described as the 'semiconductor layer 510’, the 'first gate electrode 520' is briefly described as the 'gate electrode 520,' the 'first capacitor Cst' is briefly described as the 'capacitor Cst,' the 'first lower electrode 520' is briefly described as the 'lower electrode 520,' and the 'first upper electrode 530' is briefly described as the 'upper electrode 530.'

In some embodiments, although 'FIG. 6 is a cross-sectional view schematically illustrating an example of the first transistor and the first capacitor of FIG. 5,' the present disclosure is not necessarily limited thereto, and as described below, any configuration in which the first insulating layer l1 and the gate electrode 520 of the transistor T1 and the second insulating layer l2 of the capacitor Cst are sequentially and continuously formed may be applied to the transistor T1 and the capacitor Cst of any layout. As used herein, “continuously formed” means formed in a single process step, without moving through the process line.

The present disclosure contemplates variations of the layout illustrated in FIG. 5 as long as the transistor T1, the capacitor Cst that is placed on the transistor T1, the first insulating layer l1, the gate electrode 520, and the second insulating layer l2’ are sequentially and continuously formed. In some embodiments, apart from a pixel circuit of 3 transistors and 2 capacitors (3T2C) as shown in FIG. 4, a case in which the transistor T1 and the capacitor Cst are placed on the transistor T1 may be applied to various pixel circuits.

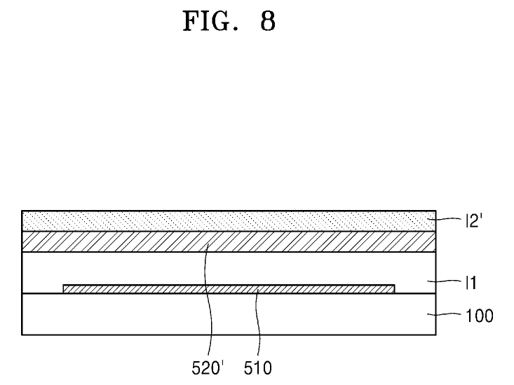

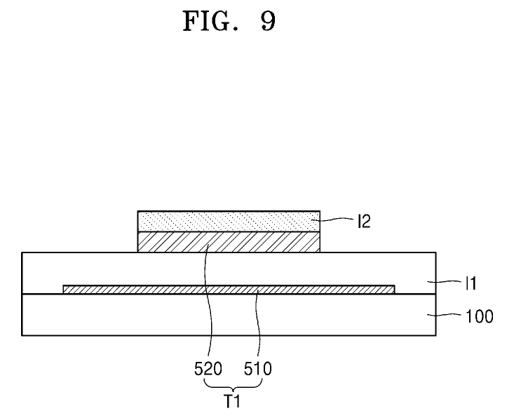

In some embodiments, the second insulating layer l2' of FIG. 8 shows a second insulating layer l2' before a patterning process, and the second insulating layer l2 of FIG. 9 shows the second insulating layer l2 after the patterning process. Accordingly, for clarity of description, the reference numbers of the second insulating layer l2' of FIG. 8 is distinguished from the second insulating layer l2 of FIG. 9.

Meanwhile, a method of manufacturing the display device 1 according to an embodiment of the present disclosure may include stacking the semiconductor layer 510 on the substrate 100, sequentially and continuously forming the first insulating layer l1, a first conductive layer 520', and the second insulating layer l2' on the semiconductor layer 510, and simultaneously patterning the first conductive layer 520' and the second insulating layer l2'. Here, the first conductive layer 520’ may be patterned to form the gate electrode 520 of the transistor T1 or the lower electrode 520 of the capacitor Cst.

In an embodiment, referring to FIG. 7, the semiconductor layer 510 may be disposed on the substrate 100. Referring to FIG. 8, the first insulating layer l1, the first conductive layer 520', and the second insulating layer l2' may be sequentially and continuously formed on the semiconductor layer 510. Here, the method of continuously forming the first insulating layer l1, the first conductive layer 520', and the second insulating layer l2' may be by chemical vapor deposition (CVD).

In the related art, the first insulating layer l1 was formed on the semiconductor layer 510, the first conductive layer 520' was formed on the first insulating layer l1, and the second insulating layer l2' was then formed on the first conductive layer 520'. In this case, contaminants occurring during the display manufacturing process could be trapped between the first conductive layer 520' and the second insulating layer l2'.

For example, during the process of forming the first conductive layer 520' on the first insulating layer l1 and moving through a process line, there was a concern that contaminants would adsorb onto the first conductive layer 520'. Accordingly, the second insulating layer l2' was required to have a minimum thickness that would prevent performance degradation of the capacitor Cst due to contaminants.

In an embodiment of the present disclosure, when the first insulating layer l1, the first conductive layer 520', and the second insulating layer l2' are continuously formed on the semiconductor layer 510 by chemical vapor deposition, there is minimal concern of the first insulating layer l1, the first conductive layer 520', and the second insulating layer l2' being contaminated during the process of moving through the process line, so the second insulating layer l2 may have a small thickness. The thickness of the second insulating layer l2' may be about 10 nm to about 150 nm.

In this manner, when the capacitor Cst includes the second insulating layer l2 that is thin, the electric capacitance of the capacitor Cst may increase, and accordingly, the electrical characteristics of the display device 1 and the electronic device including the same may be improved.

In some embodiments, as the electric capacitance of the capacitor Cst increases, the thickness of the lower electrode 520 of the capacitor Cst may also become thinner. In an embodiment, the thickness of the lower electrode 520 of the capacitor Cst (or the gate electrode 520 of the transistor) may be about 30 nm to about 250 nm, and the ratio of the thickness of the lower electrode 520 to the thickness of the second insulating layer l2 may be about 1.5 to about 5. As the thickness of the second insulating layer l2 becomes thinner, the thickness of the lower electrode 520 may also become thinner, but is not necessarily limited thereto.

In some embodiments, because the first insulating layer l1, the first conductive layer 520', and the second insulating layer l2' are successively formed on the semiconductor layer 510 by chemical vapor deposition, the manufacturing process of the display device 1 may be simplified and the efficiency of the manufacturing process of the display device 1 and the electronic device including the same may be improved.

Meanwhile, because the first insulating layer l1, the first conductive layer 520', and the second insulating layer l2' are continuously formed on the semiconductor layer 510 by chemical vapor deposition, the first conductive layer 520' needs to be a conductive material that may be formed by chemical vapor deposition. For example, the first conductive layer 520' may include, but is not limited to, amorphous silicon or amorphous silicon doped with a conductive material, and various materials may be used as long as the materials may be deposited on the first insulating layer l1 by a chemical vapor deposition method.

After the first insulating layer l1, a first conductive layer 520', and the second insulating layer l2' are successively formed on the semiconductor layer 510 by a chemical vapor deposition method, the first conductive layer 520' and the second insulating layer l2' may be patterned simultaneously. Here, the patterned first conductive layer 520' may form the gate electrode 520. Accordingly, the gate electrode 520 and the patterned second insulating layer l2 on the gate electrode 520 may have a same width w as shown in FIG. 6.

Here, the ‘width w‘ refers to a length measured in a direction perpendicular to the thickness direction of the first insulating layer l1, the gate electrode 520, and the second insulating layer l2 disposed on the semiconductor layer 510. Referring to FIG. 6, the thickness direction may be the z-direction. In some embodiments, tolerance according to a design margin may be included in the range of the 'same width w'.

That is, the simultaneously patterned gate electrode 520 and the second insulating layer l2 may have the same cross-section as shown in FIG. 6. Here, the term 'cross-section' may refer to a cross-section in a direction parallel to the thickness direction of the first insulating layer l1, the first conductive layer 520', and the second insulating layer l2. However, the direction of the cross-section is not limited thereto, and a cross-section may have a slope depending on the tolerance of the patterning process, for example, a dry etching process.

In this manner, when the first conductive layer 520’ and the second insulating layer l2’ are patterned simultaneously, the manufacturing process of the display device 1 may be simplified and the efficiency of the manufacturing process of the display device 1 and the electronic device including the same may be improved.

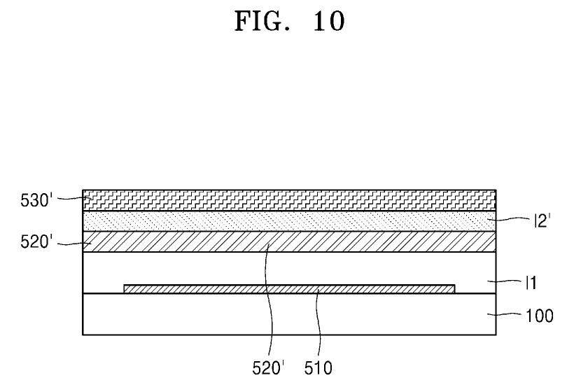

Meanwhile, following the simultaneous patterning of the first conductive layer 520' and the second insulating layer l2', a second conductive layer (530' in FIG. 10) including the upper electrode 530 may be disposed on the second insulating layer l2. Here, the second conductive layer 530' may be formed continuously together with the first insulating layer l1, the first conductive layer 520', and the second insulating layer l2', as in an embodiment described below with reference to FIG. 10. Alternatively, the second conductive layer 530' may be formed separately from the first insulating layer l1, the first conductive layer 520', and the second insulating layer l2' by a process such as sputtering.

When the second conductive layer 530' is formed separately from the first insulating layer l1, the first conductive layer 520', and the second insulating layer l2', the second conductive layer 530' may include a material other than a material that may be formed by chemical vapor deposition, thereby expanding the range of materials for the second conductive layer 530'. For example, when sputtering the second conductive layer 530' on the second insulating layer l2', the second conductive layer 530' may include at least one of aluminum, copper, titanium, tantalum, nickel, molybdenum, tungsten, chromium, gold, silver, or palladium.

After the second conductive layer 530' is disposed on the second insulating layer l2, the second conductive layer 530' is patterned to form the upper electrode 530, thereby manufacturing the transistor T1 and the capacitor Cst illustrated in FIG. 6. That is, the semiconductor layer 510, the first insulating layer l1, and the gate electrode 520 may form the transistor T1, and the lower electrode 520, the second insulating layer l2, and the upper electrode 530 may form the capacitor Cst. Here, the gate electrode 520 of the transistor T1 may refer to the same component as the lower electrode 520 of the capacitor Cst.

However, the second conductive layer 530' is not limited to being formed in the above order. For example, the first conductive layer 520’ and the second insulating layer l2' may be patterned simultaneously, the second conductive layer 530' may be patterned first and then disposed on the second insulating layer l2 using a process such as photolithography. That is, the upper electrode 530 may be first patterned and then disposed on the second insulating layer l2, or the second conductive layer 530' including the upper electrode 530 may be first disposed on the second insulating layer l2 and then patterned to form the upper electrode 530.

Meanwhile, the gate electrode 520 needs to be connected to a separate interconnection for applying a gate signal. If the upper electrode 530 and the gate electrode 520 are patterned simultaneously so that the width of the upper electrode 530 is the same as the width w of the gate electrode 520, space for connecting a separate interconnection to the gate electrode 520 may be insufficient. Therefore, as described above, the upper electrode 530 and the gate electrode 520 need to be patterned separately.

Accordingly, the width w of the formed gate electrode 520 may be larger than the width of the upper electrode 530. Here, 'width' may refer to a length measured in a direction orthogonal to the thickness direction (z-direction) of the first insulating layer l1, the first conductive layer 520', and the second insulating layer l2 stacked on the semiconductor layer 510, or a length measured along a longer side of the gate electrode 520 in FIG. 6.

In this manner, in case that the width w of the gate electrode 520 is larger than the width of the upper electrode 530, a space for connecting a separate interconnection for applying a gate signal to the gate electrode 520 may be secured and the integration of the display device 1 may also be improved.

That is, in the display device 1 according to an embodiment of the present disclosure, as illustrated in FIG. 6, the gate electrode 520 and the second insulating layer l2 may have the same width w, but the width w of the gate electrode 520 may be larger than the width of the upper electrode 530.

Meanwhile, after the transistor T1 and capacitor Cst illustrated in FIG. 6 are formed, the third insulating layer (l3 in FIG. 5) may be deposited on the first insulating layer l1 to cover the capacitor Cst, as illustrated in FIG. 5.

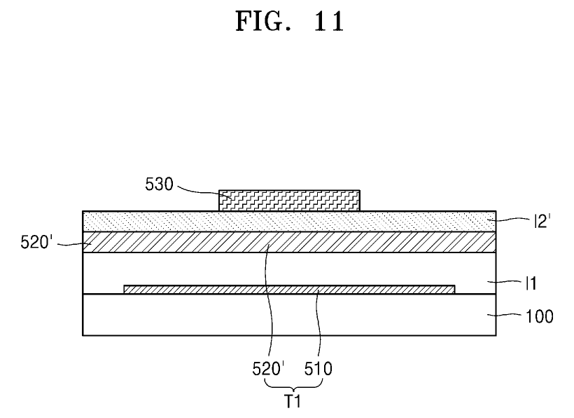

FIGS. 10 and 11 are cross-sectional views schematically illustrating another example of a method of manufacturing the first transistor T1 and the first capacitor Cst of FIG. 6.

The second insulating layer l2' of FIG. 10 represents the second insulating layer l2' before the patterning process, and the second insulating layer l2 of FIG. 11 represents the second insulating layer l2 after the patterning process. Accordingly, for clarity of description, the reference numerals of the second insulating layer l2' of FIG. 8 is distinguished from the second insulating layer l2 of FIG. 9.

Referring to FIGS. 10 and 11 together with FIG. 6, a method of manufacturing the transistor T1 and the capacitor Cst according to another embodiment of the present disclosure may include disposing the semiconductor layer 510 on the substrate 100, sequentially and continuously forming the first insulating layer l1, the first conductive layer 520', the second insulating layer l2', and the second conductive layer 530' on the semiconductor layer 510, patterning the second conductive layer 530' to form the upper electrode 530, and simultaneously patterning the first conductive layer 520' and the second insulating layer l2'.

In an embodiment, referring to FIG. 10, after the semiconductor layer 510 is disposed on the substrate 100, the first insulating layer l1, a first conductive layer 520', the second insulating layer l2', and the second conductive layer 530' may be sequentially and continuously formed on the semiconductor layer 510. Here, the method of continuously forming the first insulating layer l1, the first conductive layer 520', the second insulating layer l2' and the second conductive layer 530' may be performed by chemical vapor deposition (CVD) method.

Meanwhile, because the first insulating layer l1, the first conductive layer 520', the second insulating layer l2', and the second conductive layer 530' are continuously formed on the semiconductor layer 510 by chemical vapor deposition, the first conductive layer 520' and the second conductive layer 530' each need to be a conductive material available for chemical vapor deposition. For example, the first conductive layer 520' and the second conductive layer 530' may each include, but is not limited to, amorphous silicon or amorphous silicon doped with a conductive material, and various materials may be used as long as they are materials that may be formed on the first insulating layer l1 by a chemical vapor deposition method.

When the first insulating layer l1, a first conductive layer 520', the second insulating layer l2' and the second conductive layer 530' are continuously formed on the semiconductor layer 510 by a chemical vapor deposition method, contamination that may occur during the manufacturing process of the display device 1 may be avoided, as described above. The reduced risk of contamination allows the second insulating layer l2 of the capacitor Cst to be formed thinner than with a conventional process with a higher risk of contamination. The second insulating layer I2 being thinner increases the capacitance of the capacitor Cst and improves the electrical characteristics of the display device 1 and the electronic device including the same.

In some embodiments, because the first insulating layer l1, the first conductive layer 520', the second insulating layer l2', and the second conductive layer 530' are continuously formed on the semiconductor layer 510 by chemical vapor deposition, the manufacturing process of the display device 1 may be simplified and the efficiency of the manufacturing process of the display device 1 and the electronic device including the same may be improved.

Meanwhile, after the continuous film formation operation, the second conductive layer 530' may be patterned to form the upper electrode 530, as shown in FIG. 11. Thereafter, the first conductive layer 520' and the second insulating layer l2' may be patterned simultaneously to form the transistor T1 and the capacitor Cst including the gate electrode 520 and the second insulating layer l2 having the same width w, as shown in FIG. 6.

According to embodiments of the present disclosure, contamination of the second insulating layer l2 that may occur during the manufacturing process of the display device 1 may be prevented, thereby forming the thin second insulating layer l2. Accordingly, the capacitance of the capacitor Cst may increase, so that the electrical characteristics of the display device 1 and the electronic device including the same may be improved.

In some embodiments, because the first insulating layer l1, the gate electrode 520, the second insulating layer l2, and the second conductive layer 530' are sequentially and continuously formed and then the gate electrode 520 and the second insulating layer l2 are simultaneously patterned, the manufacturing process of the display device 1 may be simplified, thereby improving the efficiency of the manufacturing process of the display device 1.

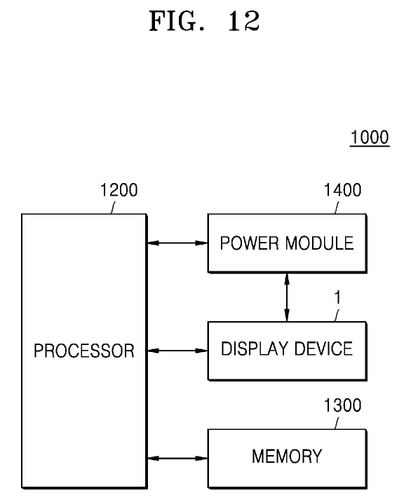

FIG. 12 is a block diagram of the electronic device 1000 according to an embodiment.

Referring to FIG. 12, the electronic device 1000 according to an embodiment may include the display device 1, a processor 1200, a memory 1300, and a power module 1400.

The display device 1 may receive data from the processor 1200 and provide visual information. The display device 1 may be the display device 1 according to the embodiments of the present disclosure described above.

The processor 1200 may include at least one of a central processing unit (CPU), an application processor (AP), a graphics processing unit (GPU), a communication processor (CP), an image signal processor (ISP), and a controller. For example, the processor 1200 may operate by executing at least one program.

The memory 1500 may store data information necessary for the operation of the processor 1200 or the display device 1. For example, the memory 1500 may store at least one of the above programs. When the processor 1200 executes an application stored in the memory 1500, an image data signal and/or an input control signal may be transferred to the display device 1, and the display device 1 may process the received signal and output image information through a display screen.

The power module 1400 may include a power supply module, such as a power adapter or a battery device, and a power conversion module that converts power supplied by the power supply module to generate power required for the operation of the electronic device 1000. For example, the power module 1400 may supply power to the display device 1.

At least one of the components of the electronic device 1000 may be included in the display device 1 according to the embodiments described above. In some embodiments, some of the individual modules functionally included within one module may be included within the display device 1 and others may be provided separately from the display device 1.

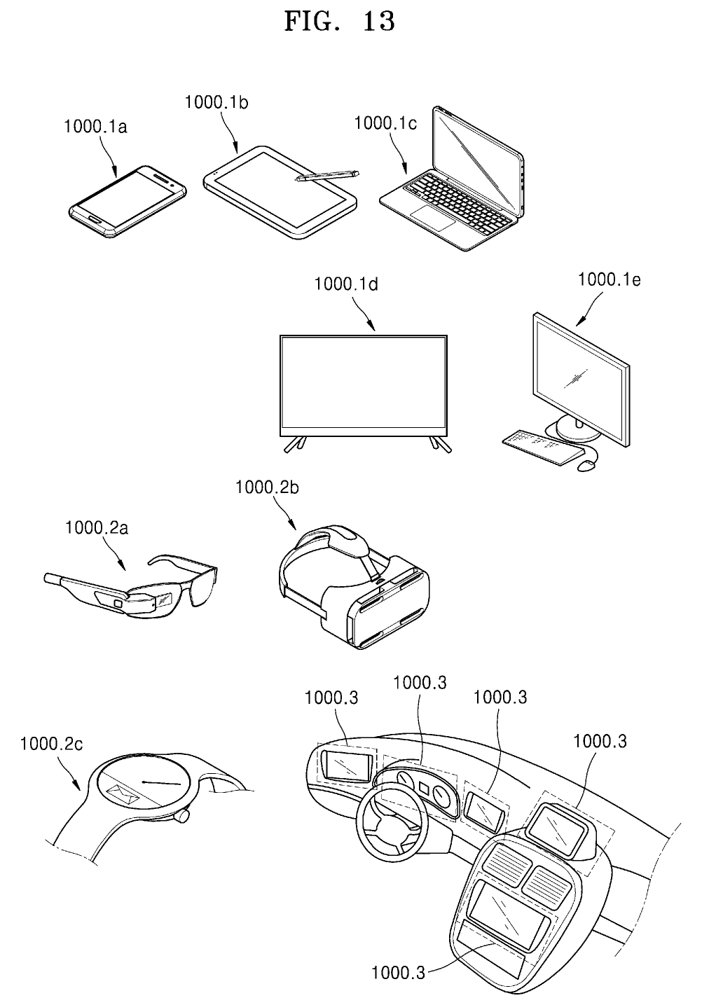

FIG. 13 is a schematic diagram of electronic devices according to various embodiments.

Referring to FIG. 13, various electronic devices to which the display device according to embodiments of the present disclosure is applied may include not only image display electronic devices, such as a smartphone 1000.1a, a tablet PC 1000.1b, a laptop 1000.1c, a TV 1000.1d, and a desk monitor 1000.1e, but also wearable electronic devices including display devices, such as smart glasses 1000.2a, a head mounted display 1000.2b, and a smart watch 1000.2c, and vehicle electronic devices 1000.3 including a display device, such as a center information display (CID) and a room mirror display positioned on an instrumental panel, a center fascia, and a dashboard of an automobile.

According to embodiments of the present disclosure, by sequentially and continuously forming the first insulating layer, the gate electrode (or lower electrode), and the second insulating layer, and then simultaneously patterning the gate electrode and the second insulating layer, the manufacturing process of the display device may be simplified, thereby improving the efficiency of the manufacturing process of the display device.

In addition, by sequentially and continuously forming the first insulating layer, the gate electrode (or lower electrode), and the second insulating layer, contamination of the second insulating layer that may occur during the manufacturing process of the display device may be prevented, thereby forming the thin second insulating layer. Accordingly, the capacitance of the capacitor may increase, and thus, the electrical characteristics of the display device and the electronic device including the same may be improved.

However, the effects obtainable through the present disclosure are not limited to the effects described above, and other technical effects not mentioned will be clearly understood by those skilled in the art from the description of the disclosure described above.

Each of the embodiments described above may be implemented independently, but the structure of each embodiment may be applied in combination to other embodiments.

As such, the present disclosure has been described with reference to the embodiments shown in the drawings, but these are merely illustrative, and those skilled in the art will understand that various modifications and equivalent other embodiments may be made therefrom. Therefore, the true scope of technical protection of the present disclosure should be determined by the technical spirit of the appended patent claims.

Specific implementations described in the embodiments are examples and do not limit the scope of the embodiments in any way. Moreover, no component is essential to the practice of the present disclosure, unless the component is for example described as “essential” or “critical”.

In the specification of the embodiment (particularly in the claims), the use of the terms “a” and “an” and “the” and similar referents may be construed to cover both the singular and the plural.

Furthermore, recitation of ranges of values herein are merely intended to serve as a shorthand method of referring individually to each separate value falling within the range, unless otherwise indicated herein, and each separate value is incorporated into the specification as if it were individually recited herein.

Lastly, the steps of all methods described herein may be performed in any suitable order unless otherwise indicated herein or otherwise clearly contradicted by context. The embodiments are not necessarily limited by the order of description of the steps above.

The use of any and all examples, or exemplary language (e.g., “such as”) provided herein is intended merely to better describe the present disclosure and the scope of the embodiments is not limited by the examples or illustrative terms, unless limited by the claims.

In addition, those skilled in the art may recognize that various modifications, combinations and changes may be made depending on design conditions and factors within the scope of the appended claims or their equivalents.

What is claimed is:

1. A display device comprising:
a substrate;
a first transistor on the substrate;
a capacitor on the first transistor connected to a gate electrode of the first transistor; and
a light-emitting device electrically connected to the first transistor,
wherein the first transistor includes a semiconductor layer and the gate electrode with a first insulating layer therebetween,
the capacitor includes a lower electrode including the gate electrode and an upper electrode with a second insulating layer therebetween, and
the second insulating layer and the gate electrode have a same width.

2. The display device of claim 1, wherein
a thickness of the gate electrode is about 30 nm to about 250 nm.

3. The display device of claim 1, wherein
a thickness of the second insulating layer is about 10 nm to about 150 nm.

4. The display device of claim 1, wherein
a ratio of a thickness of the gate electrode to a thickness of the second insulating layer is about 1.5 to about 5.

5. The display device of claim 1, wherein
a width of the gate electrode is greater than a width of the upper electrode.

6. The display device of claim 1, further comprising:
a third insulating layer on the first insulating layer to cover the capacitor.

7. The display device of claim 1, further comprising:
a second transistor and a third transistor on the capacitor,
wherein the second transistor and the third transistor are in a same layer.

8. The display device of claim 1, wherein
the gate electrode includes amorphous silicon.

9. A method of manufacturing a display device, the method comprising:
disposing a semiconductor layer on a substrate;
continuously forming a first insulating layer, a first conductive layer, and a second insulating layer sequentially on the semiconductor layer; and
simultaneously patterning the first conductive layer and the second insulating layer,
wherein the first conductive layer is patterned to form a gate electrode, and
the gate electrode and the patterned second insulating layer on the gate electrode have a same width.

10. The method of claim 9, further comprising:
disposing an upper electrode on the second insulating layer.

11. The method of claim 10, wherein
the semiconductor layer, the first insulating layer, and the gate electrode form a first transistor, and
the gate electrode, the second insulating layer, and the upper electrode form a capacitor.

12. The method of claim 9, wherein,
the continuously forming of the first insulating layer, the first conductive layer, and the second insulating layer sequentially on the semiconductor layer further comprises:
continuously and sequentially forming a second conductive layer on the second insulating layer.

13. The method of claim 12, further comprising:
patterning the second conductive layer to form an upper electrode after the continuous forming of the first insulating layer, the first conductive layer, and the second insulating layer and before the patterning of the first conductive layer and the second insulating layer.

14. The method of claim 13, wherein
a width of the gate electrode is greater than a width of the upper electrode.

15. The method of claim 12, wherein
the first insulating layer, the first conductive layer, the second insulating layer, and the second conductive layer are continuously formed using a chemical vapor deposition (CVD) method.

16. The method of claim 12, wherein
the first conductive layer and the second conductive layer each include amorphous silicon.

17. The method of claim 9, wherein
a thickness of the second insulating layer is about 10 nm to about 150 nm.

18. An electronic device comprising:
a memory storing at least one program;
a processor configured to operate by executing the at least one program;
a display device configured to receive data from the processor and to provide visual information; and
a power module configured to supply power to the display device,
wherein the display device includes:
a substrate;
a first transistor on the substrate;
a capacitor on the first transistor connected to adjust a gate electrode of the first transistor; and
a light-emitting device electrically connected to the first transistor,
wherein the first transistor includes a semiconductor layer and a gate electrode with a first insulating layer therebetween,
the capacitor includes a lower electrode including the gate electrode and an upper electrode with a second insulating layer therebetween, and
the second insulating layer and the gate electrode have a same width.

19. The electronic device of claim 18, wherein
a thickness of the second insulating layer is about 10 nm to about 150 nm.

20. The electronic device of claim 18, wherein
a ratio of a thickness of the gate electrode to a thickness of the second insulating layer is about 1.5 to about 5.
